(19) United States
(12) Patent Application Publication
(10) Pub. No.: US 2026/0218378 A1
(43) Pub. Date: Jul. 30, 2026

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Kosuke NAKAO, Toyama (JP); Mitsunori TAKESHITA, Toyama (JP); Tomohiko KADOSAKI, Toyama (JP); Hiroshi HIROTANI, Toyama (JP)

(73) Assignee: KOKUSAI ELECTRIC CORPORATION, Tokyo (JP)

(21) Appl. No.: 19/456,805

(22) Filed: Jan. 22, 2026

(30) Foreign Application Priority Data
Jan. 30, 2025 (JP) 2025-013998

(51) Int. Cl. C23C 16/44; C23C 16/40; C23C 16/455; H10P 14/692

(52) U.S. Cl. CPC C23C 16/4401; C23C 16/405; C23C 16/455; H10P 14/69392

(57) ABSTRACT

A technique includes: first and second process modules respectively including first and second process containers configured to process a substrate; first and second utilities respectively including first and second supply systems configured to supply process gas into the process containers, wherein the first and second process modules respectively include first and second outer side surfaces on sides of the first and second process modules opposite to surfaces of the process modules adjacent to each other and are parallel in a front-rear direction, wherein the first utility includes a first side box protruding outward than the first outer side surface and accommodating a part of the first supply system disposed such that maintenance is performed through access from at least one selected from the group of a front, a rear, and a top side of the first side box, and not from a side surface of the first side box.

### CROSS-REFERENCE TO RELATED APPLICATION

This application is based upon and claims the benefit of priority from Japanese Patent Application No. 2025-013998 filed on January 30, 2025 the entire content of which is incorporated herein by reference.

### TECHNICAL FIELD

The present disclosure relates to a substrate processing apparatus, a method of processing a substrate, a method of manufacturing a semiconductor device, and a recording medium.

### BACKGROUND

In the related art, there is a method of manufacturing a semiconductor device in which a vertical substrate processing apparatus may be used as an apparatus for forming an oxide film or a metal film on a substrate. In addition, there is a substrate processing apparatus that includes a plurality of boats configured to hold substrates and a plurality of process chambers configured to process the substrates and processes the substrates by sequentially loading and unloading the boats into and from each process chamber.

### SUMMARY

According to an embodiment of the present disclosure, there is provided a technique that includes: a first process module including a first process container configured to process a substrate; a second process module disposed adjacent to a side surface of the first process module and including a second process container configured to process a substrate; a first utility disposed adjacent to a rear surface of the first process module, the first utility including a first supply system configured to supply a process gas into the first process container; and a second utility disposed adjacent to a rear surface of the second process module, the second utility including a second supply system configured to supply the process gas into the second process container, wherein the first process module and the second process module respectively include a first outer side surface and a second outer side surface, which are located on sides of the first process module and the second process module opposite to surfaces of the first process module and the second process module adjacent to each other and are parallel with each other in a front-rear direction, wherein the first utility includes a first side box protruding farther outward than the first outer side surface and accommodating a part of the first supply system, and wherein the part of the first supply system accommodated in the first side box is disposed such that maintenance is capable of being performed for the part of the first supply system through access from at least one selected from the group of a front side, a rear side, and a top side of the first side box, and not through access from a side surface of the first side box.

### BRIEF DESCRIPTION OF DRAWINGS

The accompanying drawings, which are incorporated in and constitute a part of the specification, illustrate embodiments of the present disclosure.

FIG. 1 is a perspective view showing an example of a substrate processing apparatus according to an embodiment of the present disclosure.

FIG. 2 is a top view showing an example of a substrate processing apparatus according to an embodiment of the present disclosure.

FIG. 3 is a longitudinal cross-sectional view showing an example of a substrate processing apparatus according to an embodiment of the present disclosure.

FIG. 4 is a longitudinal cross-sectional view showing an example of a process furnace according to an embodiment of the present disclosure.

FIG. 5 is a front view showing an example of a front side box according to an embodiment of the present disclosure.

FIG. 6 is a rear view showing an example of a rear side box according to an embodiment of the present disclosure.

FIG. 7 is a perspective view showing an insertion state of a communication pipe between a side box and a utility system according to an embodiment of the present disclosure.

FIG. 8 is a block diagram showing a controller control system of a substrate processing apparatus according to an embodiment of the present disclosure.

FIG. 9 is a flowchart showing a method of processing a substrate according to an embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not been described in detail so as not to obscure aspects of the various embodiments.

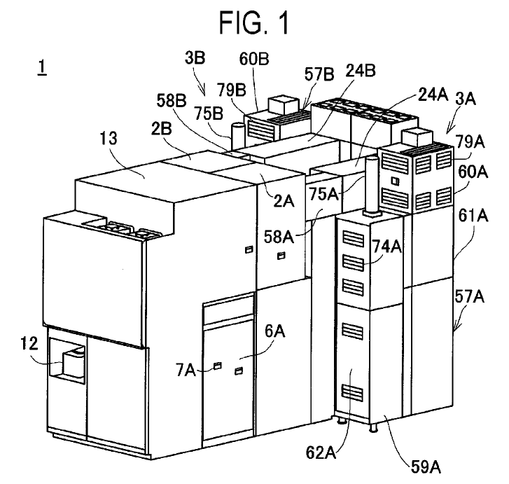

Hereinafter, one embodiment of the present disclosure will be described mainly with reference to FIGS. 1 to 9. The drawings used in the following description are schematic. Dimensional relationships, proportions, and the like of respective elements shown in the drawing may not match the actual ones. Further, dimensional relationships, proportions, and the like of respective elements may not match one another among multiple drawings. Unless otherwise specified as used herein, the number of each element is not limited to one, and a plurality of elements may exist. Throughout the drawings, the same or corresponding configurations are designated by the same or corresponding reference numerals, and redundant description thereof will be omitted. The term "agent" as used herein includes at least one selected from the group of a gaseous substance and a liquid substance. The liquid substance includes a mist-like substance. That is, a film-forming agent, a modifying agent, and an etching agent may include a gaseous substance, a liquid substance such as a mist-like substance, or both.

In addition, a side of an accommodation chamber 13 to be described later is referred to as a front surface side (front side), and a side of a first utility system 3A and a second utility system 3B to be described later is referred to as a rear surface side (rear side). Further, a side toward a boundary line (adjacent surface) of a first process module 2A and a second process module 2B to be described later is referred to as an inner side, and a side away from the boundary line is referred to as an outer side.

In the present embodiment, a substrate processing apparatus is configured as a vertical substrate processing apparatus (hereinafter referred to as a substrate processing apparatus) 1 which performs a substrate processing process such as a heating process or the like as a manufacturing process in a method of manufacturing a semiconductor device.

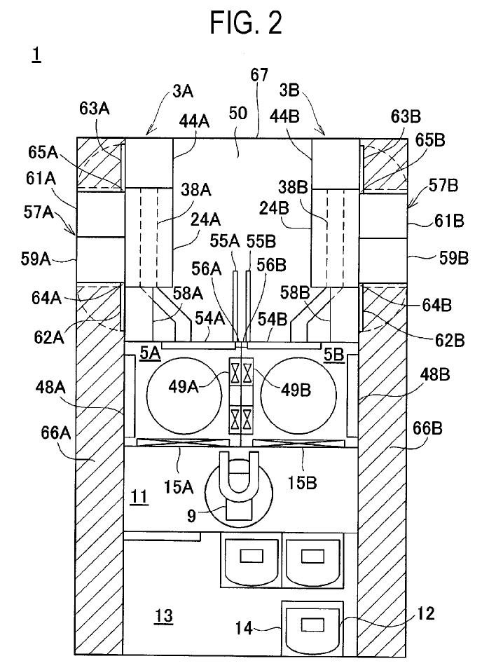

As shown in FIGS. 1 and 2, the substrate processing apparatus 1 includes a first process module 2A and a second process module 2B disposed adjacent to a right side of the process module 2A. The process modules 2A and 2B include a housing or a framework of a substantially parallelepiped contour. The process modules 2A and 2B are disposed such that side surfaces of each of the process modules 2A and 2B are in close contact with or adjacent to one another in parallel. The first utility system 3A is disposed adjacent to a rear side of the process module 2A, and the second utility system 3B is disposed adjacent to a rear side of the process module 2B.

The process module 2A includes a first process furnace 4A and a first conveyance chamber 5A disposed below the process furnace 4A. Likewise, the process module 2B also includes a second process furnace 4B and a second conveyance chamber 5B. The process modules 2A and 2B are of substantially the same configuration. When a symbol is suffixed with "A", a corresponding "B" exists even when "B" is not described in the specification or shown in the drawings.

The utility system 3A provides the process module 2A with utilities such as power, gas, compressed air, exhaust, and cooling water and control thereof. The utility system 3A is a type of shelf that extends narrowly and lengthily in a front-rear direction. A controller box 10 is disposed at an upper portion of the utility system 3A, a part of an exhaust box 44 is disposed at a middle portion of the utility system 3A, and a cooling-water box 58A, a first supply box 24A, and the other part of the exhaust box 44 are disposed at a lower portion of the utility system 3A. A height of the lower portion corresponds to the conveyance chamber 5A, and a width of the cooling-water box 58A is formed to be smaller than widths of other portions of the utility system 3A. In addition, a part of the utilities that cannot be entirely accommodated in the utility system 3A is accommodated in a first side box 57A disposed on an outer lateral side of the utility system 3A.

A transfer chamber 11 is disposed adjacent to a front surface side of the conveyance chambers 5A and 5B. The transfer chamber 11 includes a transfer device 9 that transfers a wafer 8 which serves as a substrate, and is connected to the conveyance chambers 5A and 5B respectively by a first gate valve 15A serving as a first loading port and a second gate valve 15B serving as a second loading port, which are configured to load the wafer 8. Outer diameters of the accommodation chamber 13, the process modules 2A and 2B, and the transfer chamber 11 are each based on a polyhedron including mutually orthogonal planes and the accommodation chamber 13, the process modules 2A and 2B, and the transfer chamber 11 are each configured to be detachable. Connection portions of the accommodation chamber 13, the process modules 2A and 2B, and the transfer chamber 11 are appropriately airtight.

The accommodation chamber 13 that accommodates a pod (front opening unified pod (FOUP)) 12 for accommodating a plurality of wafers 8 is connected to a front surface side of the transfer chamber 11. An input/output (I/O) port 14 is installed on the front surface of the accommodation chamber 13, and the pod 12 is loaded into or unloaded from the substrate processing apparatus 1 via the I/O port 14. A load port 16 of a front-opening interface mechanical standard (FIMS) or the like installed at the front surface of the transfer chamber 11 is disposed at the accommodation chamber 13, and the pod 12 is carried to the load port 16 by a pod conveyance device (not shown). The wafer 8 taken out of the pod 12 is handled in the transfer chamber 11 and the conveyance chambers 5A and 5B, which constitute a mini-environment.

Pressure detectors are provided in the transfer chamber 11 and in the conveyance chambers 5A and 5B, respectively, and a pressure inside the transfer chamber 11 is set to be lower than a pressure inside the conveyance chambers 5A and 5B. Oxygen concentration detectors are also provided in the transfer chamber 11 and in the conveyance chambers 5A and 5B, respectively, and oxygen concentrations inside the transfer chamber 11 and the conveyance chambers 5A and 5B are maintained to be lower than an oxygen concentration of the ambient atmosphere. A clean unit 17 that supplies clean air into the transfer chamber 11 is provided at a ceiling portion of the transfer chamber 11 and is configured to circulate clean air, for example, an inert gas, in the transfer chamber 11. By circulating and purging the transfer chamber 11 with the inert gas, a clean atmosphere can be maintained inside the transfer chamber 11. With such a configuration, it is possible to suppress an intrusion of particles from the conveyance chambers 5A and 5B into the transfer chamber 11 and to suppress a formation of a natural oxide film on the wafer 8 in the transfer chamber 11 and in the conveyance chambers 5A and 5B. A side surface of the transfer chamber 11 is constituted by a panel 6A, which is removable via a handle 7A. Maintenance of an interior of the transfer chamber 11 is made possible via the panel 6A.

Since the process modules 2A and 2B are of substantially the same (plane symmetric) configuration except for details, the process module 2A will be representatively described below.

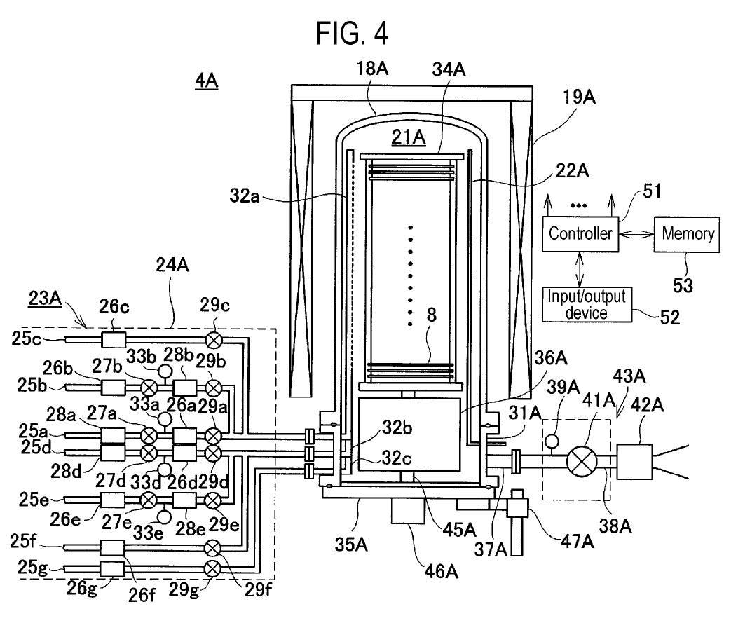

As shown in FIG. 4, the process furnace 4A includes a cylindrical first process container 18A (a reaction tube 18A) and a first heater 19A (a heater 19A) as a heating means (heating mechanism) provided at an outer periphery of the reaction tube 18A. The reaction tube 18A is made of, for example, quartz (Si). A first process chamber 21A (a process chamber 21A) for processing the wafer 8 is formed inside the reaction tube 18A. A first temperature detector 22A (a temperature detector 22A) serving as a temperature detection portion is installed upright inside the reaction tube 18A along an inner wall of the reaction tube 18A.

A process gas used for substrate processing is supplied into the process chamber 21A by a first gas supplier 23A serving as a first supply system. The gas supplier 23A constitutes a part of the utility system 3A, and gas supplied by the gas supplier 23A can be changed according to the type of a film to be formed. Here, the gas supplier 23A includes a first precursor gas supplier, a second precursor gas supplier, a third precursor gas supplier, a fourth precursor gas supplier, and a reaction gas supplier. The gas supplier 23A is accommodated in at least one selected from the group of the supply box 24A and the side box 57A, which are a part of the utility system 3A.

The first precursor gas supplier includes a gas supply pipe 25a. At the gas supply pipe 25a, a vaporizer 28a, a valve 27a serving as an opening/closing valve, a mass flow controller (MFC) 26a serving as a flow rate controller, and a valve 29a are installed in this order from an upstream side. A downstream end of the gas supply pipe 25a is connected to a nozzle 32a that penetrates a sidewall of a first manifold 31A. The first precursor gas supplier may include a first precursor gas supply source, for example, a storage container of a first liquid precursor, connected to an upstream end of the gas supply pipe 25a. A pressure sensor 33a that measures a pressure of a first precursor gas that is vaporized by the vaporizer 28a can be installed between the vaporizer 28a and the MFC 26a.

The second precursor gas supplier includes a gas supply pipe 25b. At the gas supply pipe 25b, a metering pump 26b serving as a flow rate controller, a valve 27b, a vaporizer 28b, and a valve 29b are installed in this order from an upstream side. A downstream end of the gas supply pipe 25b is connected at a downstream side of the valve 29a of the gas supply pipe 25a. The second precursor gas supplier may include a second precursor gas supply source, for example, a storage container of a second liquid precursor, connected to an upstream end of the gas supply pipe 25b.

In addition, a gas supply pipe 25c is also connected to the nozzle 32a. At the gas supply pipe 25c, an MFC 26c and a valve 29c are installed in this order from an upstream side. An upstream end of the gas supply pipe 25c is connected to a nitrogen (N₂) gas supply source serving as a gas supply source of an inert gas or a carrier gas, and a downstream end of the gas supply pipe 25c is connected to the gas supply pipe 25a at the downstream side of the valve 29a.

The nozzle 32a is installed upright inside the reaction tube 18A in a vertical direction, and a plurality of supply holes is formed so as to open toward the wafer 8 held by a first boat 34A (a boat 34A). The first precursor gas, the second precursor gas, and the inert gas are supplied separately or together to the wafer 8 through the supply holes of the nozzle 32a.

The third precursor gas supplier is of the same configuration as the first precursor gas supplier. A third precursor gas supply source includes a gas supply pipe 25d, and a downstream end of the gas supply pipe 25d is connected to a nozzle 32b that penetrates the sidewall of the manifold 31A. A third precursor gas is supplied to the wafer 8 from the third precursor gas supply source via the gas supply pipe 25d, a vaporizer 28d, a valve 27d, an MFC 26d, a valve 29d, and the nozzle 32b. The third precursor gas supplier may include a storage container of a third liquid precursor connected to an upstream end of the gas supply pipe 25d.

The fourth precursor gas supplier is of the same configuration as the second precursor gas supplier. A fourth precursor gas supply source includes a gas supply pipe 25e, and a downstream end of the gas supply pipe 25e is connected to the gas supply pipe 25d. A fourth precursor gas is supplied to the wafer 8 from the fourth precursor gas supply source via the gas supply pipe 25e, a metering pump 26e, a valve 27e, a vaporizer 28e, a valve 29e, and the nozzle 32b. The fourth precursor gas supplier may include a storage container of a fourth liquid precursor (e.g., an Hf precursor) connected to an upstream end of the gas supply pipe 25e.

Further, a gas supply pipe 25f is also connected to the nozzle 32b. The gas supply pipe 25f is installed with an MFC 26f and a valve 29f. An upstream end of the gas supply pipe 25f is connected to a nitrogen (N₂) gas supply source serving as a gas supply source of an inert gas or a carrier gas, and a downstream end of the gas supply pipe 25f is connected to the gas supply pipe 25d at a downstream side of the valve 29d.

The reaction gas supplier includes a gas supply pipe 25g, and at the gas supply pipe 25g, an MFC 26g and a valve 29g are installed in this order from an upstream side. A reaction gas supply source that supplies an oxidizing agent serving as a reaction gas is connected to an upstream end of the gas supply pipe 25g, and a downstream end of the gas supply pipe 25g is connected to a nozzle 32c that penetrates the sidewall of the manifold 31A. The oxidizing agent is supplied to the wafer 8 from the reaction gas supplier via the gas supply pipe 25g, the MFC 26g, the valve 29g, and the nozzle 32c. A gas supply pipe for supplying an inert gas may also be connected to the nozzle 32c.

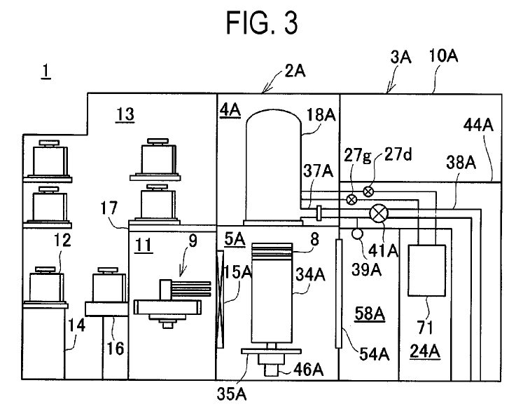

Each of the valves 29a to 29g can be constituted by a set of a supply valve installed immediately after an MFC or a vaporizer in a gas supply pipe, a final valve installed at a position closer to the nozzle, and a ventilation valve that allows a gas supply pipe immediately before the final valve and an exhaust pipe 78 to communicate. The supply valve and the final valve of each set are generally opened and closed in synchronization. The valves 27d and 27g shown in FIG. 3 correspond to the final valves.

The cylindrical manifold 31A is connected to a lower end opening of the reaction tube 18A via a seal such as an O-ring, thereby supporting the lower end of the reaction tube 18A. The lower end opening of the manifold 31A is disposed so as to correspond to a ceiling of the conveyance chamber 5A and is opened and closed by a disc-shaped first lid 35A (a lid 35A). A seal such as an O-ring is provided on an upper surface of the lid 35A, thereby airtightly sealing the reaction tube 18A from the outside air. A first heat insulator 36A (a heat insulator 36A) is placed on the lid 35A.

A first exhaust port 37A (an exhaust port 37A), which extends in a direction orthogonal to a center of an axis, that is, in a direction orthogonal to a tube axis of the reaction tube 18A, is formed at the manifold 31A. A first exhaust pipe 38A is attached to the manifold 31A via the exhaust port 37A. The exhaust pipe 38A is connected to a vacuum exhaust 42A via a first pressure sensor 39A, which serves as a pressure detector (a pressure detection part) for detecting a pressure inside the process chamber 21A, and a first conductance variable valve 41A, which serves as a pressure regulator (a pressure regulation part). The conductance variable valve 41A is also referred to as an automatic pressure controller (APC) valve. As the conductance variable value 41A, a butterfly valve can be used. With this configuration, the pressure inside the process chamber 21A can be set to a processing pressure according to processing. An exhaust system 43A serving as a first exhaust system is mainly constituted by the exhaust pipe 38A, the pressure sensor 39A, and the conductance variable valve 41A. The exhaust system 43A can be accommodated in a first exhaust box 44A to be described later.

The process chamber 21A accommodates therein a boat 34A serving as a substrate holder that vertically supports a plurality of wafers 8, for example, 10 to 150 wafers, in a shelf shape. The boat 34A is supported above the heat insulator 36A by a first rotary shaft 45A which passes through the lid 35A and the heat insulator 36A. The rotary shaft 45A is connected to a first rotator 46A installed below the lid 35A and is configured to be rotatable while airtightly sealing an interior of the reaction tube 18A. The lid 35A is driven in the vertical direction by a first boat elevator 47A serving as a elevating mechanism. Accordingly, the boat 34A and the lid 35A are raised and lowered together, and the boat 34A is loaded into and unloaded from the reaction tube 18A.

The transfer of the wafer 8 to the boat 34A is performed through the conveyance chamber 5A. As shown in FIG. 2, a first clean unit 48A is provided at one side surface of the conveyance chamber 5A (at an outer side surface of the conveyance chamber 5A, i.e., a side surface opposite to a side facing the conveyance chamber 5B) to allow clean air (e.g., inert gas) to circulate inside the conveyance chamber 5A. The inert gas supplied into the conveyance chamber 5A is exhausted from the conveyance chamber 5A by a first exhauster 49A provided at a side surface facing the clean unit 48A across the boat 34A (i.e., at the side surface facing the conveyance chamber 5B) and is resupplied into the conveyance chamber 5A from the clean unit 48A (circulatory purging). The pressure inside the conveyance chamber 5A is set to always be lower than the pressure inside the transfer chamber 11. This prevents particles and contaminants inside the conveyance chamber 5A from being introduced into the transfer chamber 11 and being spread. Further, the oxygen concentration inside the conveyance chamber 5A is set to be lower than the oxygen concentration of the ambient atmosphere.

The rotator 46A, the boat elevator 47A, the MFCs 26a, 26c, 26d, 26f, and 26g, the metering pumps 26b and 26e, the valves 27a, 27b, 27d, and 27e, the vaporizers 28a, 28b, 28d, and 28e, the valves 29a to 29g of the gas supplier 23A, and the conductance variable valve 41A are connected to a controller 51 (described later) that controls these components. The controller 51 is configured as, for example, a microprocessor (computer) including a central processing unit (CPU) and is configured to control operations of the process modules 2A and 2B. An I/O device 52 constituted as, for example, a touch panel or the like, is connected to the controller 51, and a memory 53 (described later) serving as a recording medium is connected to the controller 51. One controller 51 may be provided at each of the process module 2A and the process module 2B or may be provided to be shared by the process modules 2A and 2B. At least a part of the controller 51 is accommodated in a controller box 10A and a controller box 10B.

Next, a rear side configuration and maintenance of the substrate processing apparatus 1 will be described. As shown in FIG. 2, the utility system 3A and the utility system 3B, which are positioned close to rear surfaces of the process modules 2A and 2B and extend rearward, are provided. The utility systems 3A and 3B are disposed in a mirror-symmetrical manner, facing each other, with a maintenance area 50 interposed therebetween.

Since the utility systems 3A and 3B are of substantially the same configuration except for details, the utility system 3A will be representatively described. Outer side surfaces of the cooling-water box 58A, the supply box 24A, the exhaust box 44A, and the controller box 10A are formed on the same plane as the outer side surface of the conveyance chamber 5A. That is, when a side surface that is parallel, in the front-rear direction, to a side of the process module 2A opposite to the adjacent surface of the process modules 2A and 2B is referred to as a first outer side surface, the outer side surfaces of the cooling-water box 58A, the supply box 24A, and the exhaust box 44A coincide with the first outer side surface of the conveyance chamber 5A and are smoothly connected. Further, a side surface that is parallel, in the front-rear direction, to a side of the process module 2B opposite to the adjacent surface of the process modules 2A and 2B is referred to as a second outer side surface.

The supply box 24A accommodates the third precursor gas supplier. In order to accommodate the exhaust pipe 38A which extends rearward from the exhaust port 37A, bends downward, and extends toward the vacuum exhaust 42A located below a floor of the substrate processing apparatus 1, the exhaust box 44A is formed by connecting a box extending in the horizontal direction and a box extending in the vertical direction. The exhaust box 44A may also accommodate a part of the gas supplier 23A, such as the final valve, at a location close to the process furnace 4A.

When performing maintenance of each box of the utility systems 3A and 3B, the maintenance is performed from a space (the maintenance area 50) which is interposed between the utility systems 3A and 3B at the rear side of the process modules 2A and 2B. The maintenance area 50 is also referred to as an inner side maintenance area and secures a space for a person to perform maintenance operations from above the maintenance area 50. A floor box 67 that accommodates an exhaust duct, a cooling-water system, an electric cable, and the like may be disposed at the maintenance area 50. An upper surface of the floor box 67 is flat and is positioned lower than lower ends of maintenance doors 55A and 55B (described later), and is of sufficient strength to withstand installation or transportation of heavy objects.

As shown in FIG. 2, maintenance ports 54A and 54B are formed at the rear side of the conveyance chambers 5A and 5B, respectively. The maintenance port 54A is formed at a position offset toward the conveyance chamber 5B and a width and a height of the maintenance port 54A are set so that the reaction tube 18A and the boat 34A can be loaded and unloaded. The maintenance port 54B is formed at a position offset toward the conveyance chamber 5A and a width and a height of the maintenance port 54B are set so that the reaction tube 18B and the boat 34B can be loaded and unloaded. In addition, during maintenance, the reaction tube 18A can be lowered into the conveyance chamber 5A by the boat elevator 47A.

The maintenance ports 54A and 54B are opened and closed by the maintenance doors 55A and 55B. The maintenance doors 55A and 55B are configured to be rotatable about a first hinge 56A (a hinge 56A) and a second hinge 56B (a hinge 56B) as pivot axes. The hinge 56A is provided at the side of the conveyance chamber 5A facing the conveyance chamber 5B, and the hinge 56B is provided at the side of the conveyance chamber 5B facing the conveyance chamber 5A. Further, the maintenance area 50 can also be used for maintenance of the conveyance chamber, the process furnace, and the like. At the rear side of the conveyance chambers 5A and 5B, a space with a width and a height that do not interfere with opening and closing of the maintenance doors 55A and 55B and with loading and unloading of the reaction tube may be secured. Even when such a space cannot be secured, loading and unloading of the reaction tube is possible by removing a part of the utility system and temporarily expanding the maintenance area 50. By securing a space on the rear side of the process furnaces 4A and 4B in the same manner, the process furnaces 4A and 4B can be loaded and unloaded via the maintenance area 50.

Next, a configuration of the first side box 57A and the second side box 57B will be described with reference to FIGS. 1 and 5 to 7. The side box 57A is disposed at an outer side surface of the utility system 3A, adjacent to the supply box 24A. That is, the side box 57A is disposed so as to protrude farther outward than the outer side surface of the utility system 3A. Similarly, the side box 57B is disposed at an outer side surface of the utility system 3B, adjacent to the supply box 24B. That is, the side box 57B is disposed so as to protrude farther outward than the outer side surface of the utility system 3B.

A front surface of the side box 57A is disposed to coincide with, or to be positioned at a rear side of, a front surface of the supply box 24A (or any one of supply boxes 24A), and a rear surface of the side box 57A is disposed to coincide with, or to be positioned in front of, a rear surface of the supply box 24A (or any one of the supply boxes 24A). Similarly, a front surface of the side box 57B is disposed to coincide with, or to be positioned at a rear side of, a front surface of the supply box 24B (or any one of supply boxes 24B), and a rear surface of the side box 57B is disposed to coincide with, or to be positioned in front of, a rear surface of the supply box 24B. Further, a height of an upper surface of the side box 57A is set to be equal to that of the supply box 24A (or any one of the supply boxes 24A), and a height of an upper surface of the side box 57B is set to be equal to that of the supply box 24B (or any one of supply boxes 24B). With this configuration, a distance between a container (described later) for supplying a precursor accommodated in the side boxes 57A and 57B and the process furnaces 4A and 4B can be shortened.

Further, the side boxes 57A and 57B are configured to be integrated with the first and second outer side surfaces of the process modules 2A and 2B after the utility systems 3A and 3B are fully assembled. Bottom surfaces of the side boxes 57A and 57B are fixed to the floor (the floor box 67) by bolts, and a vicinity of upper ends of the side boxes 57A and 57B and the utility systems 3A and 3B are fixed by connecting brackets. By integrating the side boxes 57A and 57B with the utility systems 3A and 3B, the side boxes 57A and 57B can be regarded as a part of the utility in a general sense. Therefore, when the term "utility system" or "utility" is simply used herein, it may refer to a case of including the utility systems 3A and 3B or to a case including both the utility systems 3A and 3B and the side boxes 57A and 57B.

Since the side boxes 57A and 57B are of substantially the same configuration except for details, the side box 57A will be representatively described.

The side box 57A includes a front side box 59A and a rear side box 61A. The front side box 59A and the rear side box 61A are disposed so that a rear surface of the front side box 59A is adjacent to a front surface of the rear side box 61A, and the front side box 59A and the rear side box 61A are configured to be divisible. A height of the rear side box 61A is lower than that of the front side box 59A, and an electrical box 60A, which accommodates electrical equipment for controlling the side box 57A, is placed on the rear side box 61A. Further, a front side maintenance door 62A is installed at a front surface of the front side box 59A, and a rear side maintenance door 63A is installed at a rear surface of the rear side box 61A. The front side maintenance door 62A and the rear side maintenance door 63A are collectively referred to as a first maintenance door. Similarly, a front side maintenance door 62B and a rear side maintenance door 63B of the side box 57B are collectively referred to as a second maintenance door. Further, the front side box 59A and the rear side box 61A are of substantially equal widths, thereby suppressing enlargement of the side box 57A and preventing an increase in a footprint of the substrate processing apparatus 1. When the height of the front side box 59A is lower than that of the rear side box 61A, the electrical box 60A is placed on the front side box 59A. Therefore, an increase in the height of the side box 57A can be suppressed.

The front surface of the front side box 59A is opened and closed by the front side maintenance door 62A, and the rear surface of the rear side box 61A is opened and closed by the rear side maintenance door 63A. At least one of the front side maintenance door 62A or the rear side maintenance door 63A constitutes the first maintenance door of the side box 57A. Similarly, at least one of the front side maintenance door 62B or the rear side maintenance door 63B constitutes the second maintenance door of the side box 57B.

The front side maintenance door 62A and the rear side maintenance door 63A include a front side hinge 64A and a rear side hinge 65A, respectively, which rotatably support the doors toward the first outer side surface or an extended surface of the first outer side surface. Therefore, when the front side maintenance door 62A and the rear side maintenance door 63A are opened, the front side maintenance door 62A and the rear side maintenance door 63A open so as to be close to and parallel with the first outer side surface. Similarly, the front side maintenance door 62B and the rear side maintenance door 63B include a front side hinge 64B and a rear side hinge 65B, respectively, which rotatably support the doors toward the second outer side surface or an extended surface of the second outer side surface. As a result, when opened, the front side maintenance door 62A and the rear side maintenance door 63A overlap with the first outer side surface or an extended surface of first outer side surface, thereby preventing interference with maintenance operations. Furthermore, the front side hinge 64A and the rear side hinge 65A are collectively referred to as a first hinge. Similarly, the front side hinge 64B and the rear side hinge 65B of the side box 57B are collectively referred to as a second hinge.

A maintenance area 66A (also referred to an easement area) for performing maintenance of the side box 57A is formed at the front side (front) and rear side (rear) of the side box 57A and is not formed at a lateral side of the side box 57A. In other words, the maintenance area 66A is not formed at an area farther outward than a side surface of the side box 57A.

A width of the maintenance area 66A is set such that a person can pass through the maintenance area 66A and such that a precursor storage container can be loaded and unloaded into and from the maintenance area 66A. For example, when a device with a flat side surface, positioned adjacent to the substrate processing apparatus 1, is disposed close to an outer side surface of the side box 57A, a width of 610 mm or more may be secured between the side box 57A and the adjacent device at the front side or rear side of the side box 57A.

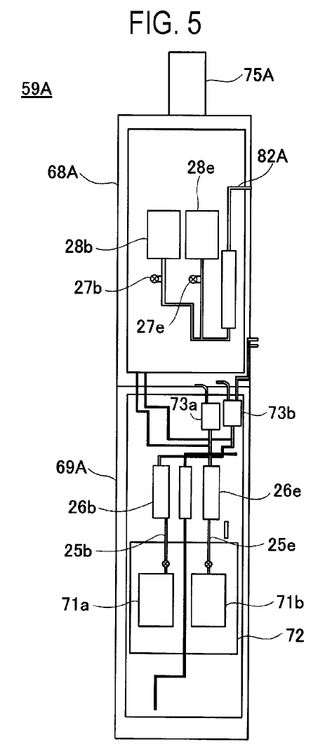

FIG. 5 shows a front view of the front side box 59A. The front side box 59A is divided into an upper side box 68A and a lower side box 69A.

Storage containers (tanks 71a and 71b), which are supply sources of a liquid precursor used for processing in the process module 2A, are accommodated in the lower side box 69A, and the tanks 71a and 71b are accommodated in a tank box 72. In the present embodiment, the second liquid precursor and the fourth liquid precursor are stored in the tanks 71a and 71b, respectively. A fire-extinguishing agent can be injected into the tank box 72 so that when an interior of the tank box 72 becomes overheated (e.g., ignition due to leakage), temperature inside the tank box 72 can be lowered or fire can be extinguished by the injection of the fire-extinguishing agent. Alternatively, the interior of the tank box 72 may be constantly purged with nitrogen (N₂) gas and a flow rate of N₂ gas may be increased at high temperature.

The vaporizers 28b and 28e corresponding to the tanks 71a and 71b are accommodated inside the upper side box 68A in a left-right arrangement. In other words, two supply systems of substantially the same height are provided side by side. Degassing devices 73a and 73b are installed between the tanks 71a and 71b of the lower side box 69A and the vaporizers 28b and 28e, respectively. In the present embodiment, each liquid precursor is configured to be squeezed by using a liquid squeezing method. In a process of squeezing the liquid precursor from the tanks 71a and 71b to the vaporizers 28b and 28e, the degassing devices 73a and 73b remove excess gas dissolved in the liquid precursor. By setting the heights of the two supply systems to be substantially equal, characteristics of the two supply systems can be aligned, and maintainability can also be improved.

As shown in FIG. 1, a suction slit 74A (a slit 74A) is formed at the front side maintenance door 62A, and an exhaust duct 75A (a duct 75A) is connected to an upper surface of the front side box 59A. By drawing external air through the slit 74A and exhausting the external air through the duct 75A, ventilation of the front side box 59A and cooling of electrical components such as the MFC 26 can be achieved. The slit 74A is formed at locations corresponding to the location of each internal electrical component so that the electrical component can be easily cooled. Although the front side box 59A of the present embodiment is divided into a two-part structure of the upper side box 68A and the lower side box 69A, ventilation performance is improved as the number of divisions increases.

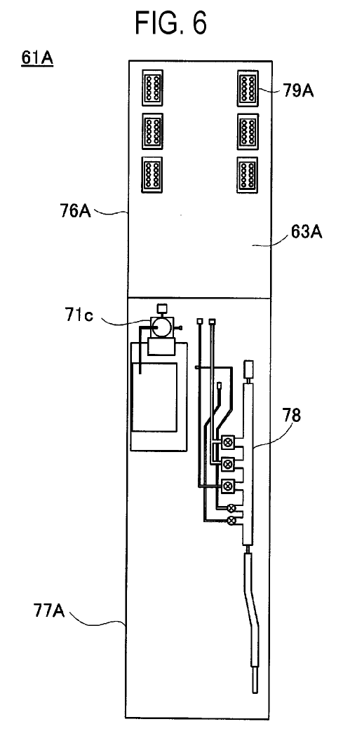

FIG. 6 shows a rear view of the rear side box 61A. The rear side box 61A is divided into an upper side box 76A and a lower side box 77A.

A tank 71c, which serves as the supply source of the first liquid precursor, and an exhaust pipe 78 are accommodated in the lower side box 77A. The tank 71c is a baking-type tank that also functions as the vaporizer 28a, and the tank 71c itself is configured to be heated so that a precursor gas vaporized in the tank 71c can be extracted. One end of the exhaust pipe 78 is connected to each of the gas supply pipes 25a to 25g and the other end of the exhaust pipe 78 is connected at a downstream side of the conductance variable valve 41 of the exhaust pipe 38A. Residual gas remaining in each of the gas supply pipes 25a to 25g can be removed via the exhaust pipe 78.

An upper surface of the upper side box 76A is set to be lower than that of the upper side box 68A. A plurality of suction slits 79A (slits 79A) is formed at predetermined positions of the rear side maintenance door 63A of the upper side box 76A. Electrical equipment for controlling components of the side box 57A are accommodated in the upper side box 76A.

The rear side box 61A is configured to draw external air through the slits 79A and exhaust the external air via an exhaust duct (not shown) formed at a bottom surface of the lower side box 77A. That is, the front side box 59A and the rear side box 61A are ventilated separately.

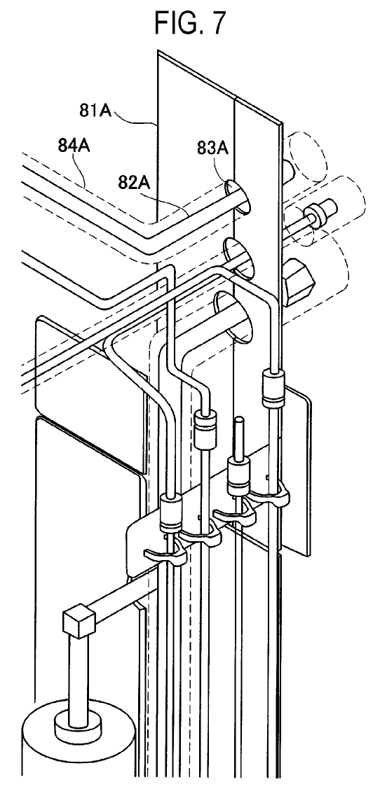

FIG. 7 shows an insertion state of a communication pipe 82A between the utility system 3A and the side box 57A. In FIG. 7, reference symbol 81A denotes a piping panel. The piping panel 81A is configured to position and secure the communication pipe 82A which connects the side box 57A and the supply box 24A. The piping panel 81A includes an insertion through-hole 83A through which the communication pipe 82A is inserted and is divided into a two-part structure at the insertion through-hole 83A. That is, the divided panels of the piping panel 81A each form a part of the insertion through-hole 83A and the insertion through-hole 83A is formed by joining the two panels.

Although not shown, a small window through which the communication pipe 82A is inserted and components that relay the communication pipe 82A from the side box 57A and absorb displacement are installed at the supply box 24A.

The communication pipe 82A is a part of the gas supply pipe 25 and supplies each precursor gas that is vaporized by the vaporizer 28 to the supply box 24A. A cylindrical pipe heater 84A is installed around the communication pipe 82A, and an interior of the communication pipe 82A is heated by the pipe heater 84A, thereby preventing the vaporized precursor gas from liquefying. Even though the pipe heater 84A is installed at a part of the communication pipe 82A in FIG. 7, the pipe heater 84A is actually installed at substantially the entirety of the gas supply pipes 25a to 25f.

A diameter of the insertion through-hole 83A is set to be equal to or slightly smaller than a diameter of the pipe heater 84A. Therefore, after installing the pipe heater 84A around the communication pipe 82A, the divided panels of the piping panel 81A are joined so as to surround the insertion through-hole 83A on the pipe heater 84A. Thus, the communication pipe 82A and the pipe heater 84A are inserted through the piping panels 81A via the insertion through-hole 83A. When the diameter of the insertion through-hole 83A is slightly smaller than the diameter of the pipe heater 84A, the insertion through-hole 83A intrudes into a heat insulation material on a surface of the pipe heater 84A, thereby securing airtightness between the insertion through-hole 83A and the pipe heater 84A. In contrast, when the diameter of the insertion through-hole 83A is larger than the diameter of the pipe heater 84A, a gap is formed between the insertion through-hole 83A and the pipe heater 84A. In this case, the gap is filled with a heat insulation material made of the same material as the insulation material of the pipe heater 84A, thereby securing airtightness between the insertion through-hole 83A and the pipe heater 84A.

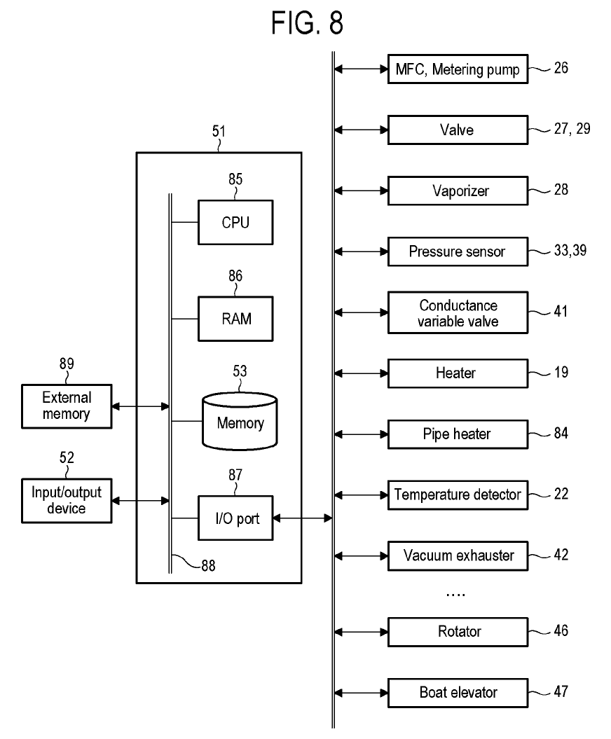

Next, a control system of the substrate processing apparatus 1 will be described. As shown in FIG. 8, the controller 51 is electrically connected to components such as the MFCs 26a, 26c, 26d, 26f, and 26g, the metering pumps 26b and 26e, and the valves 27a, 27b, 27d, 27e, and 29a to 29g, the vaporizers 28a, 28b, 28d, and 28e, the pressure sensors 33 and 39, the conductance variable valve 41, the vacuum exhaust 42, the heater 19, the pipe heater 84, the temperature detector 22, the rotators 46, and the boat elevator 47 and automatically controls these components. The controller 51 is constituted as a computer including a CPU 85, a random access memory (RAM) 86, the memory 53, and an I/O port 87. The RAM 86, the memory 53, and the I/O port 87 are configured so as to exchange data with the CPU 85 via an internal bus 88. The I/O port 87 is connected to the above-described components. The I/O device 52 constituted as, for example, a touch panel, is connected to the controller 51.

The memory device 53 includes, for example, a flash memory and a hard disk drive (HDD). A control program that controls operations of the substrate processing apparatus 1 or a program (a recipe such as a process recipe or a cleaning recipe) for executing film formation processing and the like in each component of the substrate processing apparatus 1 according to processing conditions is readably stored in the memory 53. The RAM 86 is constituted as a memory area (work area) in which programs or data read by the CPU 85 are temporarily stored.

The CPU 85 reads and executes the control program from the memory 53. The CPU 85 reads the recipe from the memory 53 in response to an input such as an operation command from the I/O device 52 and controls each component so as to follow the recipe.

The controller 51 can be configured by installing, on the computer, the above-described program continuously stored in an external memory 89 (e.g., a semiconductor memory such as a USB memory or a memory card, an optical disk such as a CD or a DVD, or an HDD.) The memory 53 or the external memory 89 is constituted as a computer-readable tangible medium. Hereinafter, the memory 53 and the external memory 89 will be generally and simply referred to as a "recording medium. " The programs may be provided to the computer by using communication means such as the Internet or a dedicated line, instead of using the external memory 89.

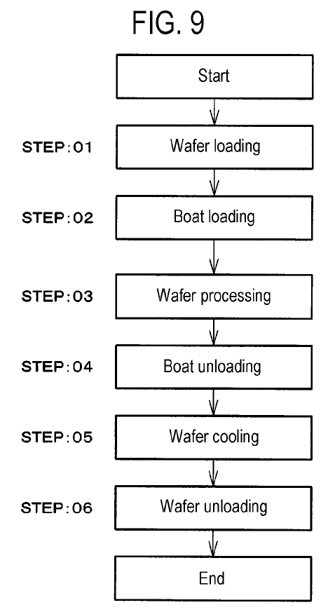

Next, a process (film formation process) of forming a film on a substrate using the above-described substrate processing apparatus 1 will be described with reference to the flowchart of FIG. 9. Here, an example will be described in which a Hf (hafnium)-containing gas serving as a precursor gas and an oxygen-containing gas serving as an oxidizing agent are supplied to the wafer 8 to form a HfO (hafnium oxide) film on the wafer 8. Since the process modules 2A and 2B are of substantially the same configuration except for details, a case in which processing is performed on the wafer 8 using the process module 2A will be described below. A processing temperature as used herein refers to a temperature of the wafer 8 or a temperature inside the process chamber 21, and a processing pressure refers to a pressure inside the process chamber 21. Further, in the following description, operations of each component constituting the substrate processing apparatus 1 is controlled by the controller 51.

### Wafer Charging and Boat Loading

The gate valve 15A is opened, and the wafer 8 is conveyed to the boat 34A (STEP: 01). When a plurality of wafers 8 is charged on the boat 34A (wafer charging), the gate valve 15A is closed. The boat 34A is loaded into the process chamber 21A by the boat elevator 47A (boat loading), and the lower end opening of the reaction tube 18A is airtightly sealed by the lid 35A (STEP: 02).

### Pressure Regulation and Temperature Regulation

The process chamber 21A is vacuum-exhausted (depressurized) to a predetermined pressure (a degree of vacuum) by the vacuum exhaust 42A. The atmosphere inside the process chamber 21A is exhausted by flowing linearly or substantially linearly through the exhaust pipe 38A. The pressure inside the process chamber 21A is measured by the pressure sensor 39A, and the conductance variable valve 41A is feedback-controlled based on the measured pressure information. Further, the process chamber 21A is heated from the surroundings by the heater 19A such that the wafers 8 inside the process chamber 21A reach a predetermined temperature. At this time, a state of supplying electric power to the heater 19A is feedback-controlled based on temperature information detected by the temperature detector 22A such that a temperature inside the process chamber 21 falls within a predetermined temperature distribution. Furthermore, the rotator 46A starts to rotate the boat 34A and the wafers 8.

### Film Formation Process

### Precursor Gas Supply Process

When the temperature inside the process chamber 21A is stabilized at a preset processing temperature, Hf gas is supplied from the fourth precursor gas supplier to the wafers 8 inside the process chamber 21A. The Hf gas is generated by pressurizing the tank 71a and squeeze a liquid precursor to the vaporizer 28e. This fresh gas is then supplied into the process chamber 21A via the gas supply pipe 25e and the nozzle 32b.

### Precursor Gas Exhaust Process

Next, the supply of the Hf gas is stopped, and the interior of the process chamber 21A is vacuum-exhausted by the vacuum exhaust 42A. The Hf gas inside the process chamber 21A flows linearly or substantially linearly through the exhaust pipe 38A and is exhausted via the vacuum exhaust 42A. At this time, the valve 29f may be opened to supply N₂ gas serving as an inert gas from the inert gas supply source into the process chamber 21A (inert gas purging.)

### Reaction Gas Supply Process

Next, the oxygen-containing gas is supplied from the reaction gas supplier to the wafers 8 inside the process chamber 21A. A flow rate of the oxygen-containing gas is controlled by the MFC 26g to reach a desired flow rate and is supplied into the process chamber 21A via the gas supply pipe 25g and the nozzle 32c.

### Reaction Gas Exhaust Process

Then, the supply of the oxygen-containing gas is stopped, and the interior of the process chamber 21A is vacuum-exhausted by the vacuum exhaust 42A. The oxygen-containing gas inside the process chamber 21A flows linearly or substantially linearly through the exhaust pipe 38A and is exhausted via the vacuum exhaust 42A. At this time, N₂ gas serving as the inert gas may be supplied from the inert gas supply source into the process chamber 21A (inert gas purging).

The above-described four processes are performed a predetermined number of times (one or more times) to form an HfO film with a predetermined composition and a predetermined film thickness on the wafers 8 (STEP: 03).

Further, at any stage before, during, or after the above-described four processes, respective precursor gases may be supplied from the first precursor gas supplier, the second precursor gas supplier, and the third precursor gas supplier. These gases may act as an adsorption-inhibiting gas, an etching gas (an gas for removing adsorption layers), a base-modifying gas, and an etch stop layer-forming gas and can be used to control selectivity, step shape, and step coverage when selectively forming the HF film. Alternatively, a film such as HfSiO₂ may also be formed by alternately depositing another film such as SiO₂.

### Boat Unloading and Wafer Discharging

After a film with a predetermined film thickness is formed, N₂ gas is supplied from the inert gas supply source, the atmosphere inside the process chamber 21A is substituted with the N₂ gas, and the pressure inside the process chamber 21A is returned to atmospheric pressure. Then, the lid 35A is lowered by the boat elevator 47A, and the boat 34A is unloaded from the reaction tube 18A (boat unloading). Thereafter, the processed wafers 8 are discharged from the boat 34A (wafer discharging) (STEP: 04).

After the boat 34A is unloaded, that is, in a state in which the opening of the reaction tube 18A is not sealed by the lid 35A, cooling of the wafers 8 and the heat insulator 36A is performed (STEP: 05). A cooling gas is supplied to the wafers 8 from a cooling gas supplier (not shown).

When the wafers 8 and the heat insulator 36A are cooled to a predetermined temperature, the processed wafers 8 charged on the boat 34A are conveyed to the pod 12 by the transfer device 9 (STEP: 06). The wafers 8 accommodated in the pod 12 are unloaded out of the substrate processing apparatus 1 and the film formation process is completed.

Processing conditions when forming the HfO film on the wafers 8 are exemplified as follows.

Processing temperature (wafer temperature): 20 degree C to 620 degree C

Processing pressure (pressure inside process chamber): 1 Pa to 4,000 Pa

Flow rate of Hf-containing gas: 1 sccm to 300 sccm

Flow rate of oxygen-containing gas: 3 sccm to 1,000 sccm

By setting each processing condition to a value within each range, the film formation process can properly proceed. A notation of a numerical range such as "1 Pa to 4,000 Pa" means that a lower limit and an upper limit are included in that range. For example, "1 Pa to 4,000 Pa" means "1 Pa or more and 4,000 Pa or less". The same applies to other numerical ranges.

Further, the process modules 2A and 2B can be configured so as to form different films, such as film A and film B. In this case, the configurations of the gas suppliers 23A and 23B differ, but the symmetry of the supply boxes 24A and 24B and the exhaust boxes 44A and 44B can be maintained. Further, the side boxes can be configured in an asymmetric configuration in which, for example, the side box 57A constituted by the front side box 59A and the side box 57B constituted by the front side box 59B. In this case, a gap between the outer side surface of the side box and an adjacent device can be narrowed to about 15 mm, and the maintenance area 66A and the maintenance area 66B of the adjacent device can be shared.

According to the present embodiment, one or more of the following effects are obtained.

In the present embodiment, the side box 57A is installed adjacent to the first outer side surface of the process module 2A, and the side box 57B is installed adjacent to the second outer side surface of the process module 2B. The side boxes 57A and 57B allow maintenance of a part of the first supply system or a part of the second supply system via access from the front or the rear via the front side maintenance doors 62A and 62B and the rear side maintenance doors 63A and 63B installed on the front surface and the rear surface, not via access from the side surface.

Therefore, maintenance area 66 may not be provided at lateral sides of the side boxes 57A and 57B, thereby suppressing an increase in footprint and enlargement of the substrate processing apparatus 1.

Further, in the present embodiment, the maintenance area 66 is formed at lateral sides of the process modules 2A and 2B by an amount corresponding to widths of the side boxes 57A and 57B. Thus, since access to the transfer chamber 11 from the later side can be performed via the maintenance area 66 and the panels 6A and 6B, the transfer chamber 11 can be easily accessed and maintenance such as replacement of the clean unit 48 can be easily performed, thereby improving work efficiency.

In particular, when a plurality of substrate processing apparatuses 1 is provided consecutively in the horizontal direction, maintenance areas 66 of adjacent substrate processing apparatuses 1 are connected to form a single maintenance area with a wide width. Therefore, replacement of the process furnaces 4A and 4B or the transfer device 9 can also be performed from this maintenance area.

Moreover, in the present embodiment, the tanks 71a and 71b in which liquid precursors are stored are accommodated in the side boxes 57A and 57B. Therefore, a large number of tanks 71 can be accommodated via the side boxes 57A and 57B without being limited by spaces inside the utility systems 3A and 3B, which allows processes that use various types of gases to be performed accordingly.

Further, the side boxes 57A and 57B are disposed adjacent to the supply boxes 24A and 24B as add-ons of the utility systems 3A and 3B. That is, since the tank 71 can be disposed near the process chamber 21, a length of a pipe (the gas supply pipe 25) from the tank 71 to the process chamber 21 can be made extremely short, thereby improving supply efficiency of the precursor gas.

In addition, the side boxes 57A and 57B are post-installed onto the fully assembled utility systems 3A and 3B. Therefore, preparing a plurality of side boxes 57 in which tanks storing different precursors are accommodated and appropriately selecting the side box 57 according to a type of film to be formed on the wafer 8 can increase the types of films applicable to the substrate processing apparatus 1.

Moreover, in the present embodiment, the side boxes 57A and 57B are respectively installed with front side maintenance doors 62A and 62B at front surfaces (at the front) thereof and rear side maintenance door 63A and 63B at rear surfaces (at the rear) thereof. However, it is possible to install either of the front side maintenance doors 62 and 63 and the rear side maintenance doors 63A and 63B at the side boxes 57A and 57B. It is also possible to install maintenance doors at an upper surface of (above) the side boxes 57A and 57B to allow maintenance of a part of the first supply system and a part of the second supply system from above.

In the present embodiment, the tanks 71a and 71b are accommodated in the front side boxes 59A and 59B. However, the tanks 71a and 71b may be accommodated in the rear side boxes 61A and 61B. Furthermore, although the two tanks 71a and 71b are accommodated in the front side boxes 59A and 59B in the present embodiment, three or more tanks may also be accommodated.

The embodiment of the present disclosure has been specifically described hereinabove. However, the present disclosure is not limited to the above-described embodiment, and various changes can be made without departing from the gist thereof.

For example, in the above-described embodiment, a case has been described in which a film containing a metal element, that is, a metal-based film, is formed using an Hf-containing gas as a precursor gas and using an oxygen-containing gas as a reaction gas. However, the present disclosure is not limited to such an embodiment. For example, the present disclosure can also be suitably applied to a case in which a silicon-containing film is produced using a silicon-containing gas as the precursor gas.

In the above-described embodiment, an example in which a film is formed on the wafer 8 has been described. However, the present disclosure is not limited to the embodiment. For example, the present disclosure can also be suitably applied to a case in which an oxidation process, a diffusion process, an annealing process, an etching process, or the like is performed on the wafer 8 or on the film formed on the wafer 8.

Further, in the above-described embodiment, an example in which a film is formed using a substrate processing apparatus including a hot-wall type process furnace has been described. The present disclosure is not limited to the above-described embodiment and can also be suitably applied to a case in which a film is formed using a substrate processing apparatus including a cold-wall type process furnace. The present disclosure can be applied to a vertical substrate processing apparatus and can also be applied to a single-wafer-type substrate processing apparatus.

According to the present disclosure in some embodiments, it is possible to suppress an increase in footprint.

While certain embodiments are described, these embodiments have been presented by way of example, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus, comprising:
a first process module including a first process container configured to process a substrate;
a second process module disposed adjacent to a side surface of the first process module and including a second process container configured to process a substrate;
a first utility disposed adjacent to a rear surface of the first process module, the first utility including a first supply system configured to supply a process gas into the first process container; and
a second utility disposed adjacent to a rear surface of the second process module, the second utility including a second supply system configured to supply the process gas into the second process container,
wherein the first process module and the second process module respectively include a first outer side surface and a second outer side surface, which are located on sides of the first process module and the second process module opposite to surfaces of the first process module and the second process module adjacent to each other and are parallel with each other in a front-rear direction,
wherein the first utility includes a first side box protruding farther outward than the first outer side surface and accommodating a part of the first supply system, and
wherein the part of the first supply system accommodated in the first side box is disposed such that maintenance is capable of being performed for the part of the first supply system through access from at least one selected from the group of a front side, a rear side, and a top side of the first side box, and not through access from a side surface of the first side box.

2. The substrate processing apparatus of claim 1,
wherein the second utility includes a second side box protruding farther outward than the second outer side surface and accommodating a part of the second supply system, and
wherein the part of the second supply system accommodated in the second side box is disposed such that maintenance is capable of being performed for the part of the second supply system through access from at least one selected from the group of a front side, a rear side, and a top side of the second side box, and not through access from a side surface of the second side box.

3. The substrate processing apparatus of claim 2,
wherein the first side box and the second side box accommodate containers serving as supply sources of precursors used for processing in the first process module and the second process module, respectively.

4. The substrate processing apparatus of claim 2,
wherein a maintenance area is formed at at least one selected from the group of the front side and the rear side of the first side box without being formed farther outward than the side surface of the first side box, and
wherein a maintenance area is formed at at least one selected from the group of the front side and the rear side of the second side box without being formed farther outward than the side surface of the second side box.

5. The substrate processing apparatus of claim 2,
wherein the first side box includes a first maintenance door at at least one selected from the group of a front surface and a rear surface of the first side box,
wherein the first maintenance door includes a first hinge configured to rotatably support the first maintenance door toward the first outer side surface or an extended surface of the first outer side surface,
wherein the second side box includes a second maintenance door at at least one selected from the group of a front surface and a rear surface of the second side box, and
wherein the second maintenance door includes a second hinge configured to rotatably support the second maintenance door toward the second outer side surface or an extended surface of the second outer side surface.

6. The substrate processing apparatus of claim 5,
wherein the first side box is disposed rearward of the rear surface of the first process module and forward of a rear surface of the first utility, and
wherein the second side box is disposed rearward of the rear surface of the second process module and forward of a rear surface of the second utility.

7. The substrate processing apparatus of claim 5,
wherein the first utility includes one or more first supply boxes accommodating another part of the first supply system,
wherein the second utility includes one or more second supply boxes accommodating another part of the second supply system,
wherein the front surface of the first side box is disposed to be flush with or positioned rearward of a front surface of any one of the first supply boxes, and
wherein the rear surface of the first side box is disposed to be flush with or positioned forward of a rear surface of any one of the first supply boxes.

8. The substrate processing apparatus of claim 7,
wherein an upper surface of the first side box is disposed such that a height of the upper surface of the first side box is equal to a height of an upper surface of any one of the first supply boxes, and
wherein an upper surface of the second side box is disposed such that a height of the upper surface of the second side box is equal to a height of an upper surface of any one of the second supply boxes.

9. The substrate processing apparatus of claim 2,
wherein the first side box and the second side box each include a front side box and a rear side box that are divisible.

10. The substrate processing apparatus of claim 9,
wherein widths of the front side box and the rear side box are substantially equal.

11. The substrate processing apparatus of claim 9,
wherein the front side box and the rear side box each include a suction slit and an exhaust duct and are ventilated independently.

12. The substrate processing apparatus of claim 9,
wherein at least one selected from the group of the front side box and the rear side box includes two supply systems of substantially equal heights installed side by side.

13. The substrate processing apparatus of claim 9,
wherein an electrical box accommodating electrical equipment configured to control the first side box or the second side box is placed on the front side box or the rear side box, whichever is lower in height.

14. A method of processing a substrate, comprising:
providing the substrate loaded via a first loading port installed at a front surface side of a first process module to a first process container which is configured to process the substrate and included in the first process module;
providing the substrate loaded via a second loading port installed at a front surface side of a second process module to a second process container which is configured to process the substrate and included in the second process module disposed adjacent to a side surface of the first process module;
supplying a process gas into the first process container from a first supply system, which is included in a first utility disposed adjacent to a rear surface of the first process module;
supplying the process gas into the second process container from a second supply system, which is included in a second utility disposed adjacent to a rear surface of the second process module; and
performing maintenance of a part of the first supply system through access from at least one selected from the group of a front side, a rear side, and a top side of a first side box, not through access from a side surface of the first side box, the first side box protruding farther outward than a first outer side surface of the first process module that is parallel in a front-rear direction and accommodating the part of the first supply system.

15. A method of manufacturing a semiconductor device, comprising the method of claim 14.

16. A non-transitory computer-readable recording medium storing a program that causes a computer included in a substrate processing apparatus to perform:
providing a substrate loaded via a first loading port installed at a front surface side of a first process module to a first process container which is configured to process the substrate and included in the first process module;
providing a substrate loaded via a second loading port installed at a front surface side of a second process module to a second process container, which is configured to process the substrate and included in the second process module disposed adjacent to a side surface of the first process module;
supplying a process gas into the first process container from a first supply system, which is included in a first utility disposed adjacent to a rear surface of the first process module;
supplying the process gas into the second process container from a second supply system, which is included in a second utility disposed adjacent to a rear surface of the second process module; and
performing maintenance of a part of the first supply system through access from at least one selected from the group of a front side, a rear side, and a top side of a first side box, not through access from a side surface of the first side box, the first side box protruding farther outward than a first outer side surface of the first process module that is parallel in a front-rear direction and accommodating the part of the first supply system.
